(19) United States
(12) Patent Application Publication
(10) Pub. No.: US 2015/0187681 A1
(43) Pub. Date: Jul. 2, 2015

(54) FLEXIBLE MICROELECTRONIC ASSEMBLY AND METHOD

(71) Applicants: Ravi V. Mahajan, Chandler, AZ (US); Nitin Deshpande, Chandler, AZ (US); John S. Guzek, Chandler, AZ (US); Adel Elsherbini, Chandler, AZ (US)

(72) Inventors: Ravi V. Mahajan, Chandler, AZ (US); Nitin Deshpande, Chandler, AZ (US); John S. Guzek, Chandler, AZ (US); Adel Elsherbini, Chandler, AZ (US)

(21) Appl. No.: 14/141,123

(22) Filed: Dec. 26, 2013

(51) Int. Cl. H01L 23/498; H01L 23/00

(52) U.S. Cl. CPC H01L 23/4985; H01L 24/81; H01L 23/49811; H01L 24/83; H01L 2224/83204; H01L 2224/83851

(57) ABSTRACT

This disclosure relates generally to a system and method including a substrate and an electronic component. The substrate includes a circuit board including a hole, a routing layer, and a first interconnect portion positioned, at least in part, within the hole. The electronic component includes a second interconnect portion, coupled to the first interconnect portion, forming an interconnect between the electronic component and the routing layer.

### TECHNICAL FIELD

The disclosure herein relates generally to a flexible microelectronic assembly and related method therefor.

### BACKGROUND

Microelectronic assemblies, such as electronic chip packages, chip packages that may be or have been electrically and/or mechanically secured to a printed circuit board (PCB) or other circuit board, discrete electronic components, and the like, have long utilized interconnects to couple electronic components of the assembly to other components either within or external to the assembly. The interconnects may be formed as permanent or semi-permanent interconnects, for instance by way of coupling solder balls to opposing pads, or may be temporary or readily de-coupleable by using sockets and the like. Traces within a PCB or within the microelectronic assembly may be coupled to the pads or bumps and/or the socket and routed to an intermediate or ultimate origin and/or destination for electrical signals transmitted to or received from the various components of the microelectronic assembly and to which the microelectronic assembly is coupled.

### BRIEF DESCRIPTION OF THE DRAWINGS

FIG. 1 is an abstract cross-sectional view of a microelectronic assembly, in an example embodiment.

FIGS. 2A-2C illustrate the forming and separation of a microelectronic assembly through the application of heat, in an example embodiment.

FIG. 3 is a narrow view of a microelectronic assembly, in an example embodiment.

FIG. 4 is an abstract cross-sectional view of a microelectronic assembly, in an example embodiment.

FIG. 5 is an abstract cross-sectional view of a microelectronic assembly in a flexed condition, in an example embodiment.

FIG. 6 is a flowchart for making a microelectronic assembly, in an example embodiment.

FIG. 7 is a block diagram of an electronic device incorporating at least one microelectronic assembly, in an example embodiment.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Microelectronic assemblies are often substantially rigid owing, at least in part, to the components that make up the assemblies. While certain microelectronic assemblies may be locally flexible where a board is flexible or includes a flexible substrate, often such assemblies are not substantially flexible around components of the assembly. For instance, an electronic chip may include a substantially inflexible silicon die encased in a substantially inflexible dielectric material. To whatever extent portions of a microelectronic assembly may be flexible, a portion of a microelectronic assembly that includes the electronic chip may conventionally be as or essentially as substantially inflexible as the electronic chip. To the extent that the PCB or substrate to which the electronic chip is attached is flexible, flexing the PCB or substrate may result in breakage of the interconnects between the electronic chip and the PCB or substrate.

A microelectronic assembly and related manufacturing process has been developed that may increase the flexibility of microelectronic assemblies even in proximity of relatively inflexible individual components. The PCB or substrate (herein after collectively referred to, without limitation, as the substrate) may be built to be flexible (though the assembly and method disclosed herein is entirely applicable to rigid or substantially rigid substrates) with holes formed therein. A substrate-portion of an interconnect may be positioned within the hole. The component may be mated to board by bringing a component-portion of the interconnect into contact with the substrate-portion of the interconnect and joining the two together to form the interconnect. As will be disclosed herein, the interconnect may thus stay in place without unduly stretching the substrate.

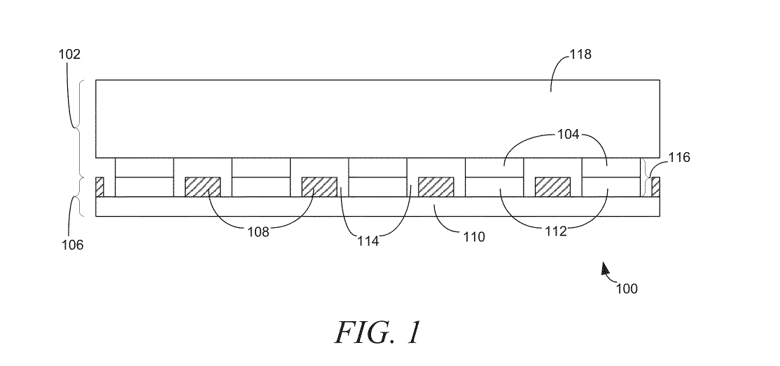

FIG. 1 is an abstract cross-sectional view of a microelectronic assembly 100, in an example embodiment. As illustrated, the microelectronic assembly includes a chip package 102 including interconnect pads 104 and a substrate 106 including a PCB 108, a routing layer 110, and interconnect solder bumps 112 within holes 114 formed in the PCB 108. The pads 104 and solder bumps 112 form interconnects 116 that provide, at least in part, electrical conductivity between the chip package 102 and the routing layer 110.

The chip package 102 may include a silicon die (obscured) within an encapsulating dielectric 118. The pads 104 may be formed of copper or other suitable conductive material. The pads 104 may be electrically coupled to the die through the dielectric 118. The pads 104 and bumps 112, and the interconnects 116 generally, may be or be replaced, in whole or in part, with non-conducting connectors. Thus, the microelectronic assembly 100 may be mechanically secured, at least in part, by various suitable fasteners that may be configured in the same or similar manner as the interconnects 116 as disclosed herein.

As illustrated, the solder bumps 112, or first interconnect portion, are electrically coupled to the routing layer 110 and are seated in within the holes 114 in the PCB 108. The routing layer 110 may formed of or include copper traces that are individually coupled to an associated solder bump 112. The routing layer 110 may be substantially flexible. The PCB 108 may variously be substantially rigid. However, because the solder bumps 112 are seated within the holes 114 of the PCB 108, flexing of the routing layer 110 may allow the solder bumps 112 one or more degrees of freedom at least partially independent of the PCB 108. Thus, the solder bumps 112 may move within the holes 114 and semi-independently of the PCB 108, thereby providing relatively more resilience against breaking the interconnect 116 that might be the case if the solder bumps 112 were fixed relative to the PCB 108.

The routing layer 110 may include a polyimide film that is sufficiently pliable to allow the interconnect 116 to remain secure during various degrees of flexing. It is to be understood that the flexibility may have limits depending on the materials used in the microelectronic assembly and their relative dimensions. In various examples, the PCB 108 may be flexible owing to the materials used and thickness or thinness. As noted herein, in various examples, the PCB 108 is substantially rigid.

While the microelectronic assembly 100 is discussed with respect to the chip package 102, the microelectronic assembly 100 may be implemented with alternative components. For instance, a silicon die may be incorporated in place of the chip package 102, one or more discrete electronic components, and the like according to the principles applied to the chip package 102. Further, the principles are expandable, such that multiple chip packages 102 or a combination and mixture of chip packages 102, dies, and discrete components may be implemented as part of the microelectronic assembly 100.

While the substrate 106 is depicted as including the PCB 108 and a separate routing layer 110, additional configurations are envisioned. For instance, the routing layer 110 may be embedded in the PCB 108. As a further example, the PCB 108 may be replaced with, for instance, a flex circuit or substrate. In such examples, however, the substrate 106, in whatever its configuration, may include solder bumps 112 within holes 114 formed in the substrate 106 generally rather than a PCB 108 specifically.

While the interconnects 116 are depicted as being formed from pads 104 and solder bumps 112, it is to be understood that the interconnects 116 may be formed by any of a variety of materials and configurations for forming interconnects and/or electrical interconnection generally. For instance, the pads 104 and solder bumps 112 may be reversed, with the solder bumps 112 included as part of the chip package 102 and the pads 104 included as part of the substrate 106. Socket technologies may be implemented, such as by coupling the solder bumps 112 to a socket into which the chip package 102 is inserted.

The interconnects 116 are formed by joining the pads 104 and the solder bumps 112, creating an electrical path between the chip package 102 and the substrate 106. As will be disclosed in detail herein, the interconnects 116 may be formed 116 by bringing the pads 104 and the solder bumps 112 into contact with one another and then causing the pads 104 and bumps 112 to be electrically and mechanically coupled with respect to one another. The interconnects 116 may be formed through the application of heat, the application of an electrically conductive polymer adhesive, the application of pressure, a combination thereof, or other suitable modes.

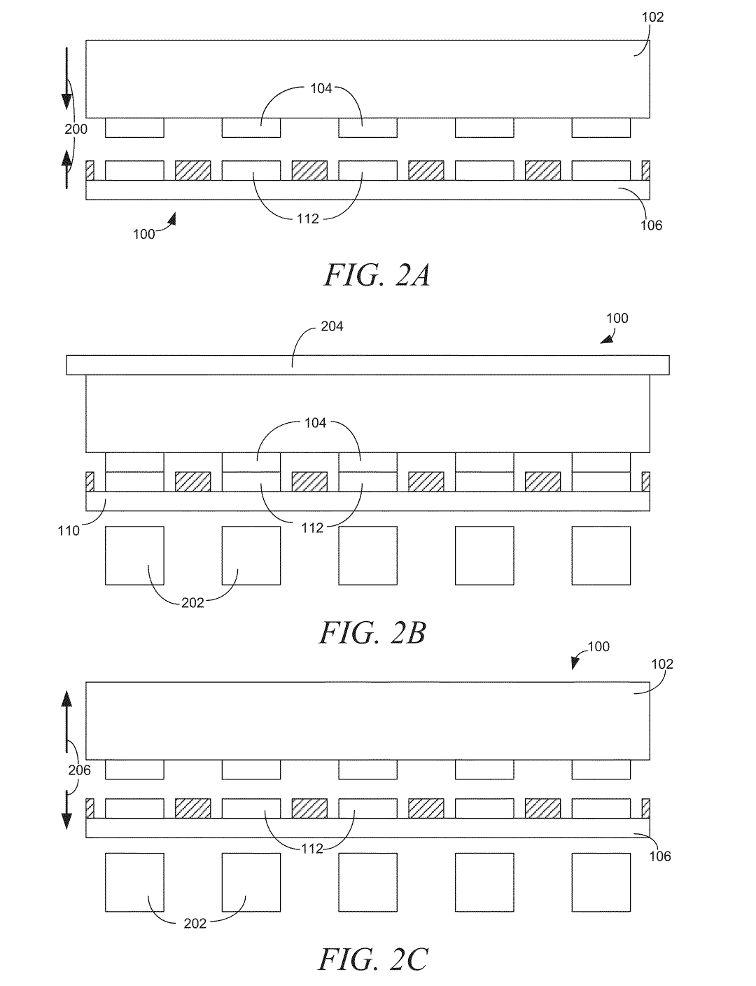

FIGS. 2A-2C illustrate the forming and separation of the microelectronic assembly 100 through the application of heat. FIGS. 2A and 2B generally relate to the forming of the microelectronic assembly 100. The microelectronic assembly 100, having been formed, may be separated into a separate chip package 102 and substrate 106 as illustrated in FIG. 2C.

In FIG. 2A, the chip package 102 is aligned with and brought into contact with the substrate 106. Arrows 200 illustrate the relative motion of the chip package 102 and the substrate 106. Proper positioning of the chip package 102 and the substrate 106 bring the opposing pads 104 and bumps 112 into alignment.

In FIG. 2B, localized heat is applied to the pads 104 and bumps 112, such as may spot weld the bumps 112 to the pads 104. In the illustrated example, localized heat is applied through the use of heated punch pads and/or columns 202. The heated punch 202 is positioned opposite the bumps 112 relative to the routing layer 110, with the heat energy conducting through the routing layer 110 to the bumps 112, which may, upon reaching the melting point of the associated material, melt, flow, and ultimately establish an electrical and mechanical connection with the pads 104. In alternative examples, the local heat may be applied from any of a variety of suitable directions and orientations to the microelectronic assembly 100, such as from the side of the microelectronic assembly.

It is to be understood that the application of heat is not necessarily local. In an example, the microelectronic assembly 100 or a portion of the microelectronic assembly 100 is heated generally, such as in an oven, the application of infrared energy, and other suitable techniques.

As illustrated, a support plate 204 may optionally provide additional rigidity during joining the chip package 102 and the substrate 106. The support plate 204 may be of particular use if the microelectronic assembly is substantially flexible. The support plate 204 may be removed upon the chip package 102 and the substrate 106 being affixed with respect to one another.

In an alternative example, the microelectronic assembly 100 is formed by applying mechanical pressure to form the interconnects 116. The interconnects 116 may, in various examples, be formed with the solder balls and pads as disclosed herein, or may be formed utilizing alternative materials that may form a resilient junction through the application of mechanical pressure, such as along the arrows 200.

In FIG. 2C, the microelectronic assembly 100 is optionally separated into the chip package 102 and the substrate 106. The local heat from the heated punch 202 may be utilized to cause the bumps 112 to reflow, whereupon the chip package 102 and the substrate 106 may be separated according to the relative motion indicated by the arrows 206. Suction may optionally be applied along with the local heat to remove the solder bumps 112 upon the bumps 112 being reflowed.

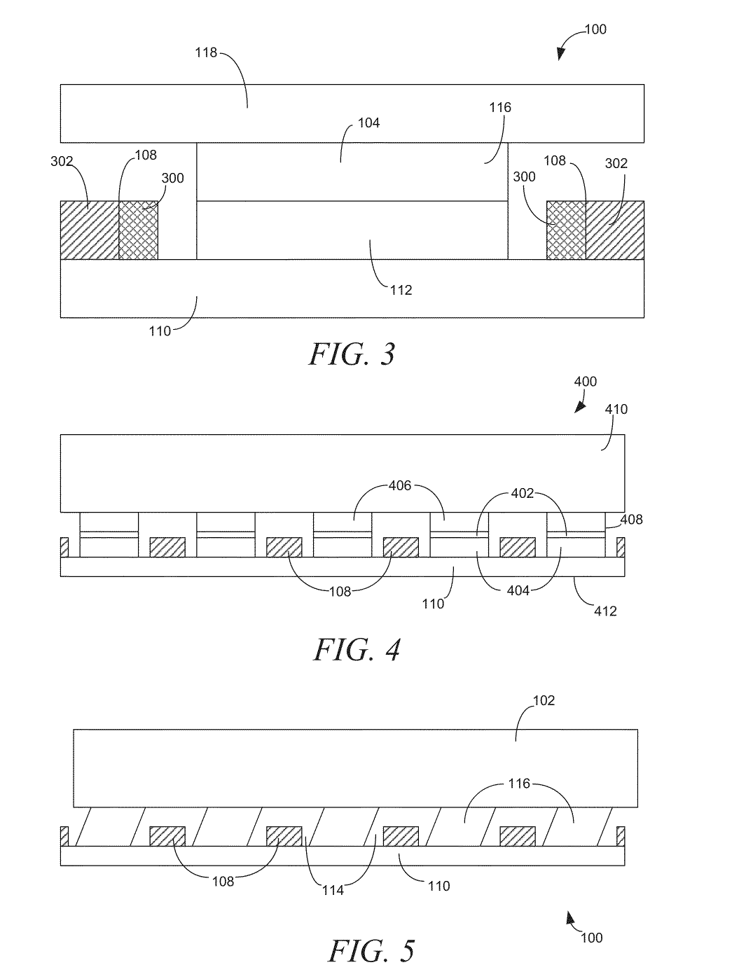

FIG. 3 is a narrower view of the microelectronic assembly 100 than presented in FIG. 1. In particular, FIG. 3 illustrates the impact of local heating on the PCB 108. As illustrated, local heating has been applied to the microelectronic assembly 100 and the pad 104 and the bump 112 are joined to form the interconnect 116. The routing layer 110 is thus electrically coupled to the die embedded in the dielectric 118.

The PCB 108 is illustrated including a chemically and/or mechanically modified area 300 owing to the effects of heating and an unmodified area 302 that is unmodified from the effects of heating. While FIG. 3 illustrates a clean delineation between the areas 300, 302, it is to be recognized and understood that, in actual implementation, there may be a gradient between the areas 300, 302, and that portions of the PCB 108 may be modified by heating to a greater or lesser degree than others.

The modified area 300 and the unmodified area 302 may stem from local heating being applied to the microelectronic assembly. In particular, because the local heating is applied substantially to the pad 104 and bump 112, portions of the PCB 108 may receive heat sufficient to cause the PCB 108 to melt or otherwise have its chemical or mechanical state changed, i.e., the modified area 300. Other portions of the PCB 108, i.e., the unmodified area 302, may not receive sufficient heat to cause a readily detectable change in the chemical or mechanical properties of the PCB material. Such may contrast with general heating, in which the PCB 108 may be uniformly or substantially uniformly chemically or mechanically modified by the general application of heat. By applying heat locally the change to the chemical and/or mechanical nature of the PCB may be reduced over the impact of general heating.

It is to be understood that the more local the heating the smaller the modified area 300 may tend to be. Thus, in various examples in which local heat is particularly narrowly applied, the PCB 108 may not include a modified area 300 at all, i.e., the PCB 108 did not have discernible chemical or mechanical change from the application of heat. In various examples, the modified area 300 may be larger or smaller depending on the nature of the local heat applied, e.g., amount of heat transferred per unit time and a degree to which the heat is focused.

FIG. 4 is an abstract cross-sectional view of a microelectronic assembly 400, in an example embodiment. The microelectronic assembly 400 incorporates many of the elements of the microelectronic assembly 100. However, rather than being formed by applying heat or pressure, the microelectronic assembly includes a conductive adhesive 402 between the first portion 404 and second portion 406 of the interconnects 408. In various examples, the conductive adhesive 402 is a conductive polymer. The microelectronic assembly may be formed by pressing the portions 404, 406 of the interconnects 408 with the adhesive 402 therebetween until a resilient junction is formed in the interconnect 408.

As illustrated, a silicon die 410 is not encapsulated in a dielectric as illustrated. However, a dielectric may optionally be added that encapsulates the die 410 as well as, optionally, some or all of the interconnects 408 and the substrate 412. The substrate 412 may include the same or substantially the same components as the substrate 106, including the PCB 108 and the routing layer 110.

FIG. 5 is an abstract cross-sectional view of the microelectronic assembly 100 in a flexed condition. It is to be understood that the illustration of the microelectronic assembly 100 in the flexed condition applies equally well to the microelectronic assembly 400 and to other microelectronic assemblies.

Where the microelectronic assembly 100 in the relaxed condition as illustrated in FIG. 1 is depicted as having generally ninety degree angles, the microelectronic assembly 100 in the flexed condition shows the interconnects 116 at non-ninety degree angles with respect to the PCB 108. As illustrated, the interconnects 116 may generally flex within the holes 114 in the PCB 108 while maintaining electrical and mechanical connectivity between the electronic component 102 and the routing layer 110.

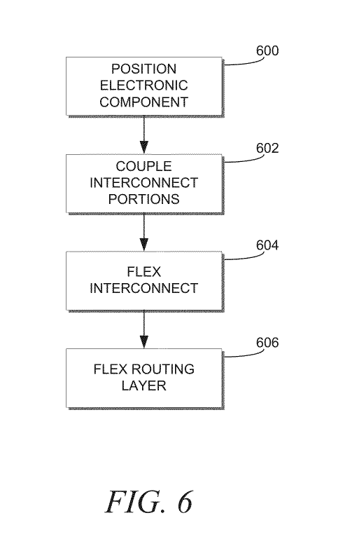

FIG. 6 is a flowchart for making a microelectronic assembly. The flowchart may be used to make the microelectronic assembly 100 or any other suitable microelectronic assembly.

At 600, an electronic component is positioned with respect to a substrate, the substrate including a circuit board forming a hole, a routing layer, and a first interconnect portion positioned, at least in part, within the hole. In an example, positioning the electronic component results in a gap between the first interconnect portion and the circuit board. In an example, positioning the electronic component with respect to the substrate includes positioning an adhesive with respect to the first interconnect portion and the second interconnect portion. In an example, the adhesive is an electrically conductive adhesive. In an example, the electronic component is at least one of an electronic chip, a silicon die, and a discrete electronic component. In an example, the first interconnect portion is a solder bump and the second interconnect portion is a pad.

At 602, the first interconnect portion is coupled with respect to a second interconnect portion of the electronic component to form an interconnect between the electronic component and the substrate. In an example, coupling the first interconnect portion includes creating a modified area of the circuit board and an unmodified area of the circuit board. In an example, coupling the first interconnect portion to the second interconnect portion includes applying heat to the first interconnect portion and the second interconnect portion and to less than all of the circuit board, wherein the modified area is indicative of applied heat to the circuit board and the unmodified area is indicative of a lack of applied heat to the circuit board. In an example, coupling the first interconnect portion to the second interconnect portion includes securing, at least in part, the first interconnect portion with respect to the second interconnect portion with the adhesive. In an example, coupling the first interconnect portion with respect to the second interconnect portion includes applying pressure between the first interconnect portion and the second interconnect portion.

At 604, the interconnected is flexed with respect to the circuit board.

At 606, the routing layer is flexed.

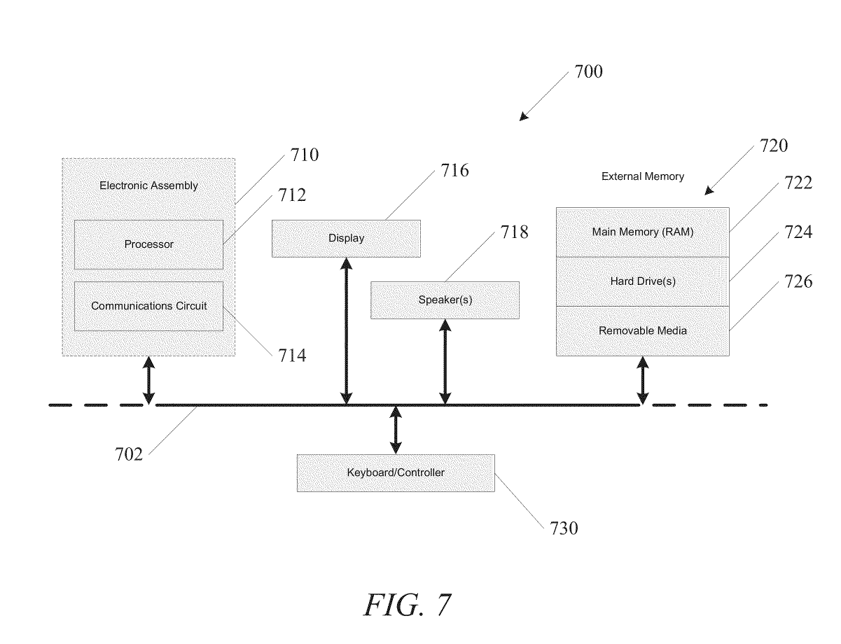

An example of an electronic device using electronic assemblies as described in the present disclosure is included to show an example of a higher level device application for the disclosed subject matter. FIG. 7 is a block diagram of an electronic device 700 incorporating at least one microelectronic assembly, such as a microelectronic assembly 100, 400 or other microelectronic assembly described in examples herein. The electronic device 700 is merely one example of an electronic system in which embodiments of the present invention can be used. Examples of electronic devices 700 include, but are not limited to personal computers, tablet computers, mobile telephones, personal data assistants, MP3 or other digital music players, wearable devices, Internet of things (IOTS) devices, etc. In this example, the electronic device 700 comprises a data processing system that includes a system bus 702 to couple the various components of the system. The system bus 702 provides communications links among the various components of the electronic device 700 and can be implemented as a single bus, as a combination of busses, or in any other suitable manner.

An electronic assembly 710 is coupled to the system bus 702. The electronic assembly 710 can include any circuit or combination of circuits. In one embodiment, the electronic assembly 710 includes a processor 712 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in the electronic assembly 710 are a custom circuit, an application-specific integrated circuit (ASIC), or the like, such as, for example, one or more circuits (such as a communications circuit 714) for use in wireless devices like mobile telephones, pagers, personal data assistants, portable computers, two-way radios, and similar electronic systems. The IC can perform any other type of function.

The electronic device 700 can also include an external memory 720, which in turn can include one or more memory elements suitable to the particular application, such as a main memory 722 in the form of random access memory (RAM), one or more hard drives 724, and/or one or more drives that handle removable media 726 such as compact disks (CD), digital video disk (DVD), and the like.

The electronic device 700 can also include a display device 716, one or more speakers 718, and a keyboard and/or controller 730, which can include a mouse, trackball, touch screen, voice-recognition device, or any other device that permits a system user to input information into and receive information from the electronic device 700.

### Additional Examples

Example 1 may include subject matter (such as an apparatus, a method, a means for performing acts) that can include a substrate, including a circuit board including a hole, a routing layer, and a first interconnect portion positioned, at least in part, within the hole, and an electronic component, including a second interconnect portion, coupled to the first interconnect portion, forming an interconnect between the electronic component and the routing layer.

Example 2 can include the subject matter of Example 1, further including that the first interconnect portion and the circuit board having a gap therebetween.

Example 3 can include the subject matter of any one or more of Examples 1 and 2, further including that the interconnect is configured to flex with respect to the circuit board.

Example 4 can include the subject matter of any one or more of Examples 1-3, further including that the routing layer is substantially flexible.

Example 5 can include the subject matter of any one or more of Examples 1-4, further including that the circuit board includes a modified area and an unmodified area.

Example 6 can include the subject matter of any one or more of Examples 1-5, further including that the modified area is indicative of applied heat to the circuit board in the formation of the interconnect and the unmodified area is indicative of a lack of applied heat to the circuit board.

Example 7 can include the subject matter of any one or more of Examples 1-6, further including an adhesive positioned with respect to the first and second interconnect portions, the adhesive securing, at least in part, the first interconnect portion with respect to the second interconnect portion.

Example 8 can include the subject matter of any one or more of Examples 1-7, further including that the adhesive is an electrically conductive adhesive.

Example 9 can include the subject matter of any one or more of Examples 1-8, further including that a junction between the first and second interconnect portions is a pressure junction.

Example 10 can include the subject matter of any one or more of Examples 1-9, further including that the electronic component is at least one of an electronic chip, a silicon die, and a discrete electronic component.

Example 11 can include the subject matter of any one or more of Examples 1-10, further including that the first interconnect portion is a solder bump and the second interconnect portion is a pad.

Example 12 may include subject matter (such as an apparatus, a method, a means for performing acts) that can include positioning an electronic component with respect to a substrate, the substrate including a circuit board forming a hole, a routing layer, and a first interconnect portion positioned, at least in part, within the hole and electrically and mechanically coupling the first interconnect portion with respect to a second interconnect portion of the electronic component to form an interconnect between the electronic component and the substrate.

Example 13 can include the subject matter of Example 12, further including that the electronic component results in a gap between the first interconnect portion and the circuit board.

Example 14 can include the subject matter of any one or more of Examples 12 and 13, further including flexing the interconnect with respect to the circuit board.

Example 15 can include the subject matter of any one or more of Examples 12-14, further including flexing the routing layer.

Example 16 can include the subject matter of any one or more of Examples 12-15, further including that coupling the first interconnect portion includes creating a modified area of the circuit board and an unmodified area of the circuit board.

Example 17 can include the subject matter of any one or more of Examples 12-16, further including that coupling the first interconnect portion to the second interconnect portion includes applying heat to the first interconnect portion and the second interconnect portion and to less than all of the circuit board, wherein the modified area is indicative of applied heat to the circuit board and the unmodified area is indicative of a lack of applied heat to the circuit board.

Example 18 can include the subject matter of any one or more of Examples 12-17, further including that positioning the electronic component with respect to the substrate includes positioning an adhesive with respect to the first interconnect portion and the second interconnect portion, and wherein coupling the first interconnect portion to the second interconnect portion includes securing, at least in part, the first interconnect portion with respect to the second interconnect portion with the adhesive.

Example 19 can include the subject matter of any one or more of Examples 12-18, further including that the adhesive is an electrically conductive adhesive.

Example 20 can include the subject matter of any one or more of Examples 12-19, further including that securing the first interconnect portion with respect to the second interconnect portion includes applying pressure between the first interconnect portion and the second interconnect portion.

Example 21 can include the subject matter of any one or more of Examples 12-20, further including that the electronic component is at least one of an electronic chip, a silicon die, and a discrete electronic component.

Example 22 can include the subject matter of any one or more of Examples 12-21, further including that the first interconnect portion is a solder bump and the second interconnect portion is a pad.

Each of these non-limiting examples can stand on its own, or can be combined with one or more of the other examples in any permutation or combination.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A microelectronic assembly, comprising:
a substrate, including:
a circuit board including a hole;
a routing layer in direct contact with the circuit board; and
a first interconnect portion coupled to the routing layer and positioned, at least in part, within the hole; and
an electronic component, including a second interconnect portion, coupled to the first interconnect portion and positioned, at least in part, outside of the hole, forming an interconnect between the electronic component and the routing layer.

2. The microelectronic assembly of claim 1, the first interconnect portion and the circuit board having a gap therebetween.

3. The microelectronic assembly of claim 2, wherein the interconnect is configured to flex with respect to the circuit board.

4. The microelectronic assembly of claim 1, wherein the routing layer is substantially flexible.

5. The microelectronic assembly of claim 1, wherein the circuit board includes a modified area and an unmodified area.

6. The microelectronic assembly of claim 5, wherein the modified area is indicative of applied heat to the circuit board in the formation of the in and the unmodified area is indicative of a tack of applied heat to the circuit board.

7. The microelectronic assembly of claim 1, further comprising an adhesive positioned with respect to the first and second interconnect portions, the adhesive securing, at least in part, the first interconnect portion with respect to the second interconnect portion.

8. The microelectronic assembly of claim 7, wherein the adhesive is an electrically conductive adhesive.

9. The microelectronic assembly of claim 1, wherein a junction between the first and second interconnect portions is a pressure junction.

10. The microelectronic assembly of claim 1, wherein the electronic component is at least one of an electronic chip, a silicon die, and a discrete electronic component.

11. The microelectronic assembly of claim 1, wherein the first interconnect portion is a solder bump and the second interconnect portion is a pad.

12. A method for making a microelectronic assembly, comprising:
positioning an electronic component with respect to a substrate, the substrate including a circuit board forming a hole, a routing layer in direct contact with the circuit board, and a first interconnect portion coupled to the routing layer and positioned, at least in part, within the hole; and
electrically and mechanically coupling the first interconnect portion with respect to a second interconnect portion of the electronic component, the second interconnect portion positioned, at least in part, outside of the hole, to form an interconnect between the electronic component and the substrate.

13. The method of claim 12, wherein positioning the electronic component results in a gap between the first interconnect portion and the circuit board.

14. The method of claim 13, further comprising flexing the interconnect with respect to the circuit board.

15. The method of claim 12, further comprising flexing the routing layer.

16. The method of claim 12, wherein coupling the first interconnect portion includes creating a modified area of the circuit board and an unmodified area of the circuit board.

17. The method of claim 16, wherein coupling the first interconnect portion to the second interconnect portion includes applying heat to the first interconnect portion and the second interconnect portion and to less than all of the circuit board, wherein the modified area is indicative of applied heat to the circuit board and the unmodified area is indicative of a lack of applied heat to the circuit board.

18. The method of claim 12, wherein positioning the electronic component with respect to the substrate includes positioning an adhesive with respect to the first interconnect portion and the second interconnect portion, and wherein coupling the first interconnect portion to the second interconnect portion includes securing, at least in part, the first interconnect portion with respect to the second interconnect portion with the adhesive.

19. The method of claim 18, wherein the adhesive is an electrically conductive adhesive.

20. The method of claim 12, wherein coupling the first interconnect portion with respect to the second interconnect portion includes applying pressure between the first interconnect portion and the second interconnect portion.

21. The method of claim 12, wherein the electronic component is at least one of an electronic chip, a silicon die, and a discrete electronic component.

22. The method of claim 12, wherein the first interconnect portion is a solder bump and the second interconnect portion is a pad.
